(19) United States
(12) Patent Application Publication
(10) Pub. No.: US 2008/0054246 A1
(43) Pub. Date: Mar. 6, 2008

(54) SEMICONDUCTOR DEVICE

(75) Inventor: Natsuki SATO, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 11/847,750

(22) Filed: Aug. 30, 2007

(30) Foreign Application Priority Data
Sep. 6, 2006 (JP) 2006-241487

(51) Int. Cl. H01L 45/00

(52) U.S. Cl. 257/4; 257/E45.002

(57) ABSTRACT

A semiconductor device including a contact plug connected to a diffusion layer of a cell transistor, a heater electrode connected to a phase-change film, and a buffer plug connecting between the contact plug and the heater electrode.

This application is based upon and claims the benefit of priority from Japanese patent application No. 2006-241487, filed on Sep. 6, 2006, the disclosure of which is incorporated herein in its entirety by reference.

### BACKGROUND OF THE INVENTION

1. Field of the Invention

The present invention relates to a semiconductor device and more particularly to a semiconductor device including a nonvolatile memory having a phase-change film.

2. Description of the Related Art

Semiconductor memories used in semiconductor devices are classified into volatile memories that do not retain the stored information when the power is turned off and nonvolatile memories that can retain the stored information even when the power is turned off. Examples of the volatile memories include DRAMs (Dynamic Random Access Memories) and SRAMs (Static Random Access Memories), and examples of the nonvolatile memories include EEPROMs (Electrically Erasable Programmable Read Only Memories) and flash memories. In many of recent personal digital assistant devices, flash memories that can retain the stored information when the power is turned off are used for achieving the miniaturization and the electric power saving.

Further, recently, a phase-change memory having a phase-change film has been increasingly used to achieve further miniaturizing and electric power saving. The phase-change memory is a nonvolatile memory storing information by using two different crystalline states of a phase-change film. The amorphous, high resistance state and the crystalline, low resistance state of the phase-change film are used to represent “1” or “0” of stored information. Such a phase-change film contains a chalcogenide.

FIGS. 1A and 1B are circuit diagrams of phase-change memory cells, and FIGS. 2 and 3 show the cross-sectional views of the cells. In the memory cell shown in FIG. 1A, one end of a variable resistance composed of a phase-change film is connected to a bit-line, the other end of the variable resistance is connected to a drain diffusion layer of a cell transistor, a source diffusion layer of the cell transistor is connected to a constant potential (GND) wiring, and a gate electrode of the cell transistor is connected to a word-line. The variable resistance has a high resistance value when the phase-change film is in an amorphous state, and has a low resistance value when the phase-change film is in a crystalline state. In addition, as in the memory cell shown in FIG. 1B, the bit-line and the constant potential (GND) wiring may be exchanged so that one end of the variable resistance is connected to the constant (GND) wiring and that the drain diffusion layer of the cell transistor is connected to the bit-line. In such a case, a current flows in the opposite direction.

The data in a memory cell is rewritten by activating a word-line to turn the cell transistor ON and thereby changing the crystalline state of the phase-change film by a current flowing through the bit-line. The phase-change film is supplied with Joule heat sufficient for heating the film to 600° C. or more for melting the film once and then is rapidly cooled to produce an amorphous state (Reset status) with a high resistance. Alternatively, the phase-change film is supplied with Joule heat in an amount of a little less than the above and then is gradually cooled to produce a crystalline state (Set status) with a low resistance. The quantity of heat and the cooling rate are controlled by the value and length (application time) of the current pulse applied to the phase-change film from the bit-line. The data in the memory cell is retrieved by activating the word-line to turn the cell transistor ON and utilizing the difference in the current value flowing through the bit-line depending on whether the phase-change film is in an amorphous state or in a crystalline state.

FIGS. 2 and 3 show the cross-sectional views of related art phase-change memory cells.

A first related art memory cell shown in FIG. 2 includes a cell transistor, a heater electrode 1, a phase-change film 3, an upper electrode 4, and a GND wiring 7. The cell transistor has a drain diffusion layer 10, a source diffusion layer 6, and a gate electrode 5. The source diffusion layer 6 is connected to the GND wiring 7 via a plug. The gate electrode 5 is connected to a word-line. The drain diffusion layer 10 is connected to the heater electrode 1. The phase-change film 3 is disposed on the upper face of the heater electrode 1, and the upper electrode 4 is disposed on the upper face of the phase-change film 3. The upper electrode 4 is connected to a bit-line. The phase-change film 3 generates heat by the flow of an electric current obtained by applying a voltage between the upper electrode 4 and the GND wiring 7. Thereby, the phase-change film 3 changes the phase at the interface with the heater electrode 1 to change the series electric resistance. In this event, the area where the temperature is increased to about 600° C. or more and the change of phase occurs is referred to as a phase-change region 2.

The gate electrode 5 connected to a word-line is activated to electrically conduct the cell transistor, and a memory cell is selected. By applying a pulse voltage to the upper electrode 4, an electric current flows from the upper electrode 4 to the GND wiring 7 through the phase-change film 3, the heater electrode 1, the drain diffusion layer 10, and the channel and the source diffusion layer 6 of the cell transistor. Specifically, the electric current flows in only the selected memory cell with the cell transistor electrically conducted. The rewriting of data in the memory cell selected is carried out by changing the phase of the phase-change film by a rewriting current. The retrieving of data is carried out by retrieving an electric current flow as memory data. Herein, the size of the electric current depends on the resistance value of the phase-change film.

In the related art shown in FIG. 2, the heater electrode 1 is directly connected to the drain diffusion layer 10. The heater electrode 1 forms an ohmic contact with the diffusion layer by being composed of, for example, a deposition of Ti (titanium), a deposition of TiN (titanium nitride) serving as a barrier metal, and a deposition of W (tungsten) for embedding. That is, the heater electrode 1 is composed of a material having a very low resistance. The heat amount is proportional to i²Rt (i: electric current, R: heater resistance, t: time applied with pulse voltage). Since the value of R is small, a large amount of electric current is necessary for generating heat sufficient to cause a change in the phase.

Furthermore, a smaller contact area between a heater electrode 1 and a phase-change film 3 produces a higher current density. Consequently, the heat generation efficiency is enhanced. However, since the heater electrode 1 shown in FIG. 2 has a large depth, it is difficult to form a heater electrode 1 having a small diameter. Therefore, the phase change requires a flow of a large amount of electric current. Accordingly, the current capability of the cell transistor must be large and thereby the size of the cell transistor is increased. Thus, the memory cell has disadvantages that the cell size is increased and the cost performance as a memory is decreased. Furthermore, since the heater electrode 1 has high heat conductivity, a larger amount of the generated heat diffuses toward the lower side as shown by the arrow. Thus, there is a disadvantage that the heat is not effectively used.

In a second related art shown in FIG. 3, the heater electrode 1 in FIG. 2 is used as a contact plug 8, and a heater electrode 21 is disposed on the upper face of the contact plug 8. The phase-change film 3 and the drain diffusion layer 10 are connected via the heater electrode 21 and the contact plug 8. In this manner, a two-stage structure is used. With this structure, the heater electrode 21 can have a small depth and therefore can have a small diameter. Furthermore, the heat generation efficiency can be increased by forming the heater electrode 21 by a material, for example, TiN having a resistance higher than that of the material of the contact plug 8.

However, when heat is generated at the interface of the heater electrode 21 and the phase-change film 3 by the electric current flowing heater electrode 21, the heat of the heater electrode 21 diffuses to the contact plug 8 having low resistance. This heat diffusion to the contact plug 8 causes a reduction in the thermal efficiency. Therefore, the electric current must be increased for compensating this reduction of the thermal efficiency. As a result, the current capability of the cell transistor must be increased. Thus, disadvantages that the heat diffusion to the contact plug 8 is large and the heat generation efficiency is low still remain.

As described above, the heater electrode has disadvantages that the electrode must be formed of a material having high resistance and be formed so as to have a small diameter for enhancing the heat generation efficiency to generate heat of 600° C. or more. In addition, there is a problem that heat diffusion must be prevented for increasing the thermal efficiency.

Phase-change memories are disclosed in the following Patent Documents. Japanese Unexamined Patent Application Publication No. 2005-51122 (Patent Document 1) discloses a phase-change memory having a structure in which a heat-blocking layer connecting a diffusion layer and an upper electrode, a heater electrode, a phase-change film, and another heat-blocking layer have the same size. In Japanese Unexamined Patent Publication No. 2006-510219 (Patent Document 2), a heater electrode has a high resistance at the phase-change film side and a low resistance at the bottom, so that an electric current is uniformly supplied to the entire high resistance portion. In Japanese Unexamined Patent Application Publication No. 2004-349709 (Patent Document 3), a contact plug is disposed at the lower side of one contact hole, a side wall is disposed at the upper side of the contact hole, and a heater electrode is disposed inside the side wall. In addition, the upper face of the heater electrode is oxidized to increase the specific resistance at an area where a phase-change film is in contact with.

### SUMMARY OF THE INVENTION

The rewriting of data in a phase-change memory requires a change in the crystalline state of a phase-change film, namely, to a crystalline, low resistance state (Set status) or to an amorphous, high resistance state (Reset status). For achieving the phase change, a heater electrode must generate a heat of 600° C. or more to melt crystals of the phase-change film for changing the crystalline state. In order to obtain such high temperature, a large electric current is necessary. However, the current capability of a memory cell depends on the current capability of a cell transistor. Therefore, when a large electric current is required for rewriting data, the cell transistor must have high current capability. In order to achieve this high current capability, it is necessary to increase the channel width of the cell transistor.

However, a larger channel width of the cell transistor causes a larger size of the memory cell and eventually an increase in the chip size. Consequently, the cost performance of the memory is decreased. Therefore, in order to achieve a small-sized memory cell without a reduction in the cost performance, it is necessary to produce the phase change with a small rewriting current. In other words, it is very important challenges to realize a structure in which a heater electrode efficiently generates heat and the heat hardly diffuses to the outside for inhibiting a decrease in temperature.

From the viewpoint of the above-mentioned challenges, the present invention provides a structure which can prevent heat diffusion toward the lower direction from a heater electrode, enhance thermal efficiency, and produce a phase change with a small rewriting current.

Therefore, it is an object of the present invention to provide a semiconductor device including a phase-change memory which can efficiently rewrite data with a small rewriting current.

Basically, the present invention employs the technology described below, in order to solve the above-mentioned problems. In addition, various modifications which are not apart from the scope of the present invention are included in the present application.

The semiconductor device according to the present invention includes a contact plug connected to one diffusion layer of a cell transistor and a heater electrode connected to a phase-change film and further includes a buffer plug connecting between the contact plug and the heater electrode.

In the semiconductor device of the present invention, the contact plug, the buffer plug, and the heater electrode are separately disposed in the respective interlayer insulating films and are stacked in the direction perpendicular to a semiconductor substrate in this order from the semiconductor substrate side so as to have the centers at substantially the same position vertically.

In the semiconductor device of the present invention, the buffer plug has a diameter smaller than that of the contact plug, and the heater electrode has a diameter smaller than that of the buffer plug.

Furthermore, the buffer plug has a specific electrode higher than that of the contact plug, and the heater electrode has a specific resistance higher than that of the buffer plug.

The contact plug of the semiconductor device of the present invention contains tungsten (W).

The buffer plug of the semiconductor device of the present invention contains TiN (titanium nitride) deposited by a CVD (chemical vapor deposition) method.

The heater electrode of the semiconductor device of the present invention contains any one selected from the group consisting of TiN (titanium nitride), TiSiN (titanium silicon nitride), TiAIN (titanium aluminum nitride), C (carbon), CN (carbon nitride), MoN (molybdenum nitride), TaN (tantalum nitride), Ptlr (platinum irridium), TiCN (titanium carbon nitride), and TiSiC (titanium silicon carbon).

The heater electrode of the semiconductor device of the present invention has an upper face implanted with oxygen, nitrogen, carbon, or silicon for further increasing the specific resistance of the top.

The phase-change memory of the present invention has a multistage structure, composed of the contact plug, the buffer plug, and the heater electrode, between the diffusion layer of the cell transistor and the phase-change film. The contact plug, the buffer plug, and the heater electrode are separately disposed in the respective interlayer insulating films and are stacked in the direction perpendicular to a semiconductor substrate so as to have the centers at approximately the same position vertically. In the order of the contact plug, the buffer plug, and the heater electrode, the heater electrode has the highest specific resistance and the smallest diameter. Since the heater electrode has a small diameter and a high resistance, the current density is large and the heat generation efficiency is high. In addition, the heat diffusion can be reduced by slightly increasing the resistance of the buffer plug. In this manner, the heat generation efficiency can be improved, and the rewriting current necessary for rewriting data (phase change) can be reduced. Consequently, the cell transistor and the cell can be miniaturized, and a semiconductor device including a phase-change memory which is small and can efficiently perform the rewriting process can be obtained.

### BRIEF DESCRIPTION OF THE DRAWINGS

FIG. 1A is a circuit diagram of a phase-change memory cell;

FIG. 1B is another circuit diagram of a phase-change memory cell;

FIG. 2 is a cross-sectional view of a phase-change memory cell according to a first prior art;

FIG. 3 is a cross-sectional view of a phase-change memory cell according to a second prior art;

FIG. 4 is a cross-sectional view of a phase-change memory cell according to the present invention; and

FIG. 5 is a cross-sectional view of another phase-change memory cell according to the present invention.

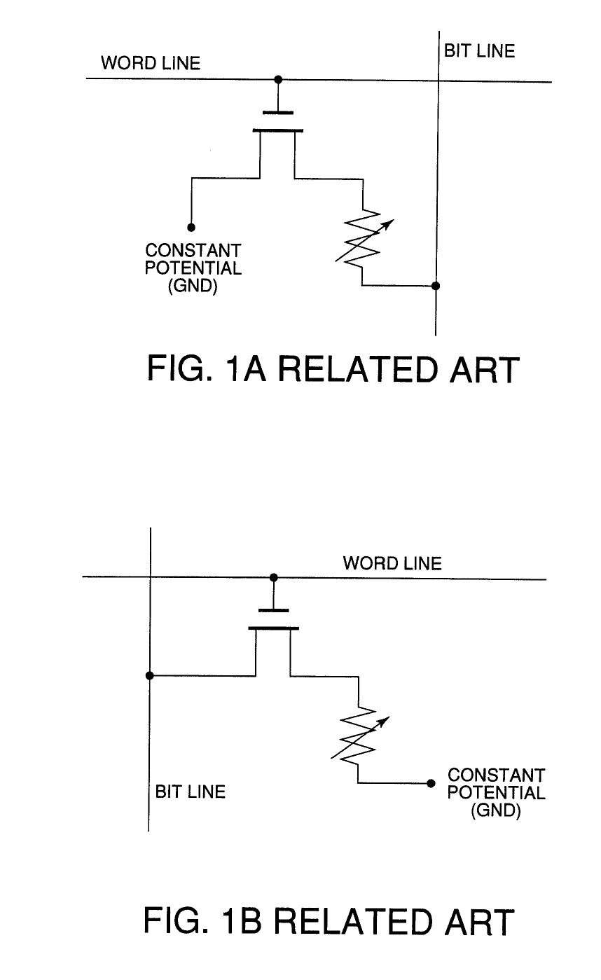

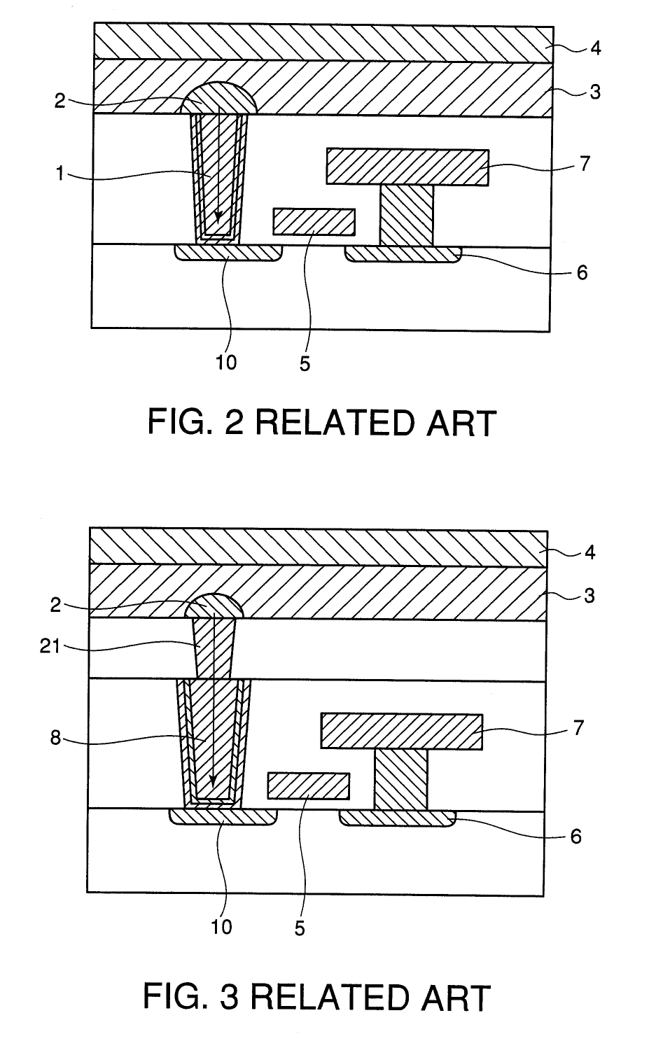

### DESCRIPTION OF THE PREFERRED EMBODIMENTS

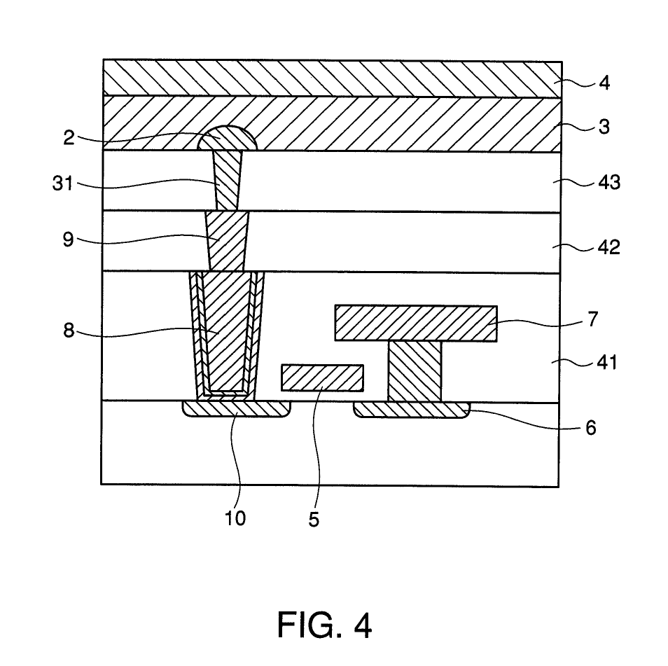

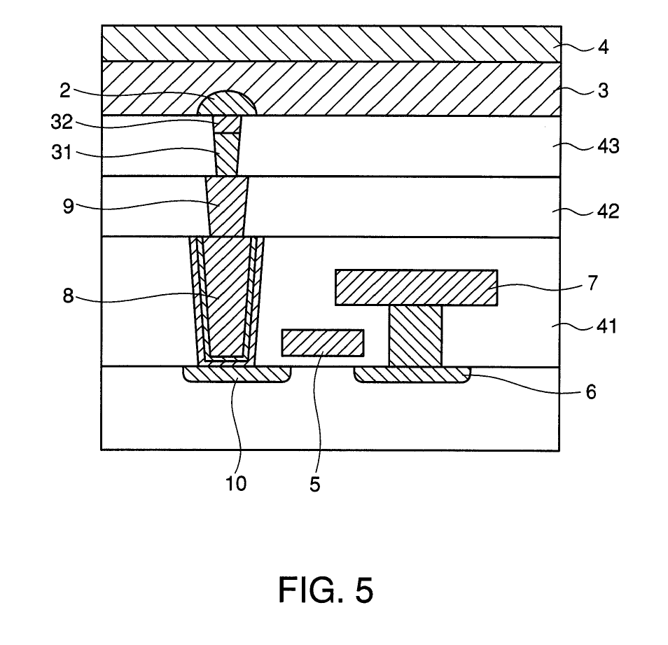

A semiconductor device according to the present invention will now be described in detail with reference to FIGS. 4 and 5. FIG. 4 is a cross-sectional view of a phase-change memory cell of the present invention. FIG. 5 is a cross-sectional view of another phase-change memory cell of the present invention. The semiconductor device of the present invention includes a buffer plug 9. Specifically, a three-stage structure composed of a heater electrode 31, the buffer plug 9, and a contact plug 8 connects between a phase-change film 3 and a drain diffusion layer 10.

The memory cell shown in FIG. 4 includes a cell transistor, a contact plug 8, a buffer plug 9, a heater electrode 31, a phase-change film 3, an upper electrode 4, and a GND wiring 7. The cell transistor is composed of a drain diffusion layer 10, a source diffusion layer 6, and a gate electrode 5. The source diffusion layer 6 is connected to the GND wiring 7 via a plug. The gate electrode 5 is connected to a word-line. The drain diffusion layer 10 is connected to the heater electrode 31 via the contact plug 8 and the buffer plug 9. Furthermore, the phase-change film 3 is disposed on the upper face of the heater electrode 31, and the upper electrode 4 is disposed on the upper face of the phase-change film 3. The phase of the phase-change film 3 is changed around the interface with the heater electrode 31 by applying a voltage between the upper electrode 4 and the GND wiring 7. Thereby, the series electric resistance is changed. In this event, the area where the phase-change occurs is referred to as a phase-change region 2.

In the present invention, the heater electrode 31 is disposed on the top of the buffer plug 9. The buffer plug 9 is disposed on the top of the contact plug 8. Further, a layer of the phase-change film 3 lies on the upper face of the heater electrode 31, and the upper electrode 4 is disposed on the phase-change film 3. By applying a pulse voltage to the upper electrode 4, a current flows from the upper electrode 4 to the GND wiring 7 through the phase-change film 3, the heater electrode 31, the buffer plug 9, the contact plug 8, and the cell transistor. In this case, heat is generated in the interface between the heater electrode 31 and the phase-change film 3 to produce the phase change of the phase-change film 3 at this area so that a change in the series electric resistance is created.

The contact plug 8, the buffer plug 9, and the heater electrode 31 are separately disposed in the respective interlayer insulating films and are stacked in the direction perpendicular to a semiconductor substrate in this order from the bottom so as to have the centers at approximately the same position vertically. In the order of the contact plug 8, the buffer plug 9, and the heater electrode 31, the heater electrode 31 has the highest specific resistance and the smallest diameter. The contact plug 8 forms an ohmic contact with the diffusion layer by being composed of, for example, a deposition of Ti, a deposition of TiN serving as a barrier metal, and a deposition of W for embedding. Thus, the contact plug 8 is made of a material having a very low resistance.

The buffer plug 9 is formed of a material, such as TiN, having a resistance higher than that of the contact plug 8. In general, a material having a high resistance has a low heat conductivity. Since the buffer plug 9 has a diameter smaller than that of the contact plug 8 and has a resistance higher than that of the contact plug 8, the heat generated in the heater electrode 31 hardly diffuses to the lower direction. Further, the heater electrode 31 has a diameter smaller than that of the buffer plug 9 and has a resistance higher than that of the buffer plug 9. Thus, a structure having a high current density and a high heat generation efficiency is obtained by decreasing the diameter and increasing the resistance.

Thus, with a multistage structure including the buffer plug 9 intervening between the contact plug 8 and the heater electrode 31, the aspect ratios of holes opening to the respective interlayer insulating films can be reduced so that optimum diameters can be selected. In addition, the resistances can be adjusted to the respective optimum values. The buffer plug 9 lying at the middle has a medium diameter and a medium specific resistance. Since the buffer plug 9 has a low heat conductivity, the heat generated in the interface between the heater electrode 31 and the phase-change film 3 hardly diffuses to the contact plug 8 disposed at the lower side. Consequently, the heat is transmitted to the phase-change film 3 disposed at the upper side. Accordingly, the thermal efficiency is improved and the current necessary for rewriting can be reduced, compared to those in the related structure. As a result, data in a memory cell can be rewritten even if the current capability of the cell transistor is low. In addition, the cell transistor size is small and thereby the cell size can be reduced, resulting in an improvement in the cost performance of the memory.

Next, a method of producing the heater electrode according to the present invention will be described. A cell transistor and a GND wiring 7 are formed by ordinary processes, and then a first interlayer insulating film 41 is formed. A contact hole is formed in the interlayer insulating film 41 so that a drain diffusion layer 10 is exposed. The contact hole is filled with an electrically conductive film to form a contact plug 8. The contact plug 8 forms an ohmic contact with a diffusion layer by being composed of, for example, a deposition of Ti (titanium), a deposition of TiN (titanium nitride) serving as a barrier metal, and a deposition of W (tungsten) for embedding. The deposited electrically conductive films are planarized by CMP (Chemical Mechanical Polishing).

Thus, the contact plug 8 is formed so as to have low reactivity with the diffusion layer and to have a very low resistance value. For example, the specific resistance of W, which is a main material of the contact plug 8, is 7 μΩ·cm. The total specific resistance of the contact plug 8, which includes Ti and TiN in addition to W, is about 20 μΩ·cm. In a contact plug having a diameter of 200 nm and a depth of 600 nm, the resistance of the contact plug is 3.8Ω. A contact plug 8 having a lower resistance value, specifically, 10Ω or less, is preferred.

Then, a second interlayer insulating film 42 is formed, and a contact hole is formed in this second interlayer insulating film 42 so that the upper face of the contact plug 8 is exposed. The contact hole is filled with an electrically conductive film to form a buffer plug 9 so that the buffer plug 9 has the center at the position approximately corresponding to the center of the contact plug 8. The buffer plug 9 has a diameter smaller than that of the contact plug 8 and has a specific resistance higher than that of the contact plug 8.

The buffer plug 9 is formed of, for example, TiN. In general, a material having a high resistance has a low heat conductivity. A structure in which the heat generated in the heater electrode 31 hardly diffuses to the lower direction can be given by forming the buffer plug 9 by a material with a resistance higher than that of the contact plug 8. For example, a TiN buffer plug formed by a usual CVD (Chemical Vapor Deposition) method has a specific resistance of 200 to 500 μΩ·cm. In a buffer plug 9 having a diameter of 100 to 120 nm and a depth of 200 nm, the resistance of the buffer plug 9 is 35 to 127Ω. The resistance of the buffer plug 9 is adjusted to 10Ω or more and 200Ω or less in order to reduce the heat conductivity.

Subsequently, a third interlayer insulating film 43 is formed, and a contact hole is formed in this third interlayer insulating film 43 so that the upper face of the buffer plug 9 is exposed. The contact hole is filled with an electrically conductive film with a high specific resistance to form a heater electrode 31 serving as a heating element so that the heater electrode 31 has the center at the position approximately corresponding to the centers of the contact plug 8 and the buffer plug 9. Further, the heater electrode 31 has a diameter smaller than that of the buffer plug 9. With this smaller diameter, the current density flowing in the heater electrode 31 can be increased. The heater electrode 31 is formed of a material with a specific resistance higher than that of the buffer plug 9.

Examples of the material with a high resistance used for the heater electrode 31 include TiN (titanium nitride), TiSiN (titanium silicon nitride), TIAIN (titanium aluminum nitride), C (carbon), CN (carbon nitride), MoN (molybdenum nitride), TaN (tantalum nitride), Ptlr (platinum irridium), TiCN (titanium carbon nitride), and TiSiC (titanium silicon carbon).

Herein, the buffer plug 9 and the heater electrode 31 are formed of the same TiN, but the specific resistances of the both are different from that of each other by varying deposition conditions of TiN. In general, the specific resistance of Ti is about 42 μΩ·cm and the specific resistance of TiN is about 200 μΩ·cm, but these specific resistances can be increased by varying deposition conditions. For example, TiN formed by a CVD (Chemical Vapor Deposition) method using a TiCl₄ (titanium tetrachloride) gas can have a specific resistance of 200 to 500 μΩ·cm. Furthermore, TiN formed by a MO-CVD (Metal Organic Chemical Vapor Deposition) method using a Ti(N(CH₃)₂)₄ (tetrakis(dimethylamino) titanium: TDMAT) gas can have a further high specific resistance of about 4500 μΩ·cm.

The heater electrode 31 is made of TiN having a specific resistance of 1000 μΩ·cm or more. In a heater electrode 31 having a diameter of 50 to 70 nm, a depth of 100 to 130 nm, and a specific resistance of 1000 μΩ·cm, the resistance of the heater electrode 31 is 260 to 660Ω. When the resistance is designated by a specific resistance, for example, the contact plug 8 is formed of a material having a specific resistance of 50 μΩ·cm or less, the buffer plug 9 is formed of a material having a specific resistance of 100 μΩ·cm or more, and the heater electrode 31 is formed of a material having a specific resistance of 1000 μΩ·cm or more. When the contact plug 8, the buffer plug 9, and the heater electrode 31 are each composed of a plurality of films, the specific resistance value is the average specific resistance value obtained according to the thickness of each laminated film.

Then, a phase-change film 3 is deposited, and then an upper electrode 4 is deposited thereon. The phase-change film 3 may be made of, for example, a material containing at least any two of germanium (Ge), antimony (Sb), tellurium (Te), selenium (Se), gallium (Ga), and indium (In). Examples of such a material include gallium antimonide (GaSb), indium antimonide (InSb), indium selenide (InSe), antimony telluride (Sb₂Te₃), germanium telluride (GeTe), Ge₂Sb₂Te₅, InSbTe, GaSeTe, SnSb₂Te₄, and InSbGe.

Next, a structure of another memory cell will be described with reference to FIG. 5. The memory cell shown in FIG. 5 is different from that of FIG. 4 in that a high-resistance portion 32 having a resistance higher than that of the heater electrode 31 is formed at a part of the top of the heater electrode 31. In the heater electrode 31, the area of contact of a heater electrode 31 and a phase-change film 3 is desired to most efficiently generate heat. Therefore, the high-resistance portion 32 is formed by further increasing the specific resistance of the top of the heater electrode 31 at the area being brought into contact with the phase-change film 3. For example, a heater electrode 31 is formed, and then the specific resistance of the top of the heater electrode 31 can be further increased by implanting, for example, nitrogen ions into the heater electrode 31 from the upper face. The specific resistance may be increased by implanting ions of nitrogen (N), oxygen (O), carbon (C), or silicon (Si). In addition, the specific resistance may be increased by supplying nitrogen or oxygen from plasma or by thermal oxidation. The high-resistance portion 32 may be formed in a part of the top of the heater electrode 31 as shown in FIG. 5 or may be formed in the entire heater electrode 31.

The phase-change memory of the present invention has a multistage structure composed of the contact plug 8, the buffer plug 9, and the heater electrode 31 between the diffusion layer 10 of the cell transistor and the phase-change film 3. The contact plug 8, the buffer plug 9, and the heater electrode 31 are separately disposed in the respective interlayer insulating films 41,42 and 43 and are stacked in the direction perpendicular to a semiconductor substrate in this order from the semiconductor substrate side so as to have the centers at approximately the same position vertically. In the order of the contact plug 8, the buffer plug 9, and the heater electrode 31, the heater electrode 31 has the highest specific resistance and the smallest diameter. Since the heater electrode 31 has a small diameter and a high resistance, the current density is large and the heat generation efficiency is high. In addition, the heat diffusion can be reduced by slightly increasing the resistance of the buffer plug 9. Thereby, the heat generation efficiency can be enhanced, and the rewriting current necessary for rewriting data (phase change) can be reduced. Consequently, the cell transistor and the cell can be miniaturized in size. In this manner, a semiconductor device including a phase-change memory which is small and can efficiently perform the rewriting process can be obtained.

The present invention is specifically described based on the embodiments above, but is not limited to these embodiments. The present invention can be variously modified without departing from the scope of the present invention, and such modifications are included in the present invention.

What is claimed is:

1. A semiconductor device, comprising:
a cell transistor having a diffusion layer;
a phase-change film;
a contact plug connected to the diffusion layer;
a heater electrode connected to the phase-change film; and
a buffer plug connected between the contact plug and the heater electrode.

2. The semiconductor device according to claim 1, wherein:
the contact plug, the buffer plug, and the heater electrode are separately disposed in respective interlayer insulating films and are stacked in a direction perpendicular to a semiconductor substrate in this order from the semiconductor substrate side so as to have centers at substantially the same position vertically.

3. The semiconductor device according to claim 2, wherein:
the buffer plug has a diameter smaller than that of the contact plug, and the heater electrode has a diameter smaller than that of the buffer plug.

4. The semiconductor device according to claim 2, wherein:
the buffer plug has a specific resistance higher than that of the contact plug, and the heater electrode has a specific resistance higher than that of the buffer plug.

5. The semiconductor device according to claim 4, wherein:
the contact plug contains tungsten.

6. The semiconductor device according to claim 4, wherein:
the buffer plug contains titanium nitride deposited by a Chemical Vapor Deposition method.

7. The semiconductor device according to claim 4, wherein:
the heater electrode contains any one selected from the group consisting of TiN (titanium nitride), TiSiN (titanium silicon nitride), TiAIN (titanium aluminum nitride), C (carbon), CN (carbon nitride), MoN (molybdenum nitride), TaN (tantalum nitride), Ptlr (platinum irridium), TiCN (titanium carbon nitride), and TiSiC (titanium silicon carbon).

8. The semiconductor device according to claim 7, wherein:
a top of the heater electrode has a portion with a higher specific resistance formed by implantation of oxygen, nitrogen, carbon, or silicon ions from an upper face.
